(19) United States
(12) Patent Application Publication
(10) Pub. No.: US 2024/0063323 A1
(43) Pub. Date: Feb. 22, 2024

(54) METHOD FOR PRODUCING A BORON EMITTER ON A SILICON WAFER

(71) Applicant: HANWHA Q CELLS GMBH, Bitterfeld-Wolfen (DE)

(72) Inventors: Enrico JARZEMBOWSKI, Bitterfeld-Wolfen (DE); Maximilian KAUERT, Bitterfeld-Wolfen (DE); Stefan PETERS, Bitterfeld-Wolfen (DE)

(21) Appl. No.: 18/257,078

(22) PCT Filed: Dec. 14, 2021
(86) PCT No.: PCT/DE2021/101003

§ 371 Date: Aug. 8, 2023

(30) Foreign Application Priority Data
Dec. 14, 2020 (DE) 102020133390.0

(51) Int. Cl. H01L 31/18

(52) U.S. Cl. CPC H01L 31/1864; H01L 31/1876; H01L 31/1804; H01L 31/184; H01L 31/0336

(57) ABSTRACT

A method for producing a boron emitter on at least one silicon wafer, arranged in a tube furnace, including: a step for forming borosilicate glass on the silicon wafer, including in the sequence given: a) evacuating the tube furnace to a specified pressure, b) feeding reagents, having BCU and O2, into the tube furnace and adjusting to a further specified pressure, c) stopping the supply after expiry of a specified period and allowing the reagents supplied to react with each other and a surface of the silicon wafer for a specified period to form a layer of borosilicate glass on the surface of the silicon wafer, and d) evacuating the tube furnace on expiry of the specified period.

### RELATED APPLICATIONS

The present application is a National Phase entry of PCT Application No. PCT/DE2021/101003, filed Dec. 14, 2021, which claims priority to German Patent Application No. 10 2020 133 390.0, filed Dec. 14, 2020, the disclosures of which are hereby incorporated by reference herein in their entirety.

### FIELD OF THE INVENTION

The invention relates to a method for producing a boron emitter on a silicon wafer. The invention in particular relates to a method for producing a boron emitter on a silicon wafer that comprises a step for forming borosilicate glass. The production of boron emitters on silicon wafers plays a part in particular in the production of wafer solar cells.

### BACKGROUND OF THE INVENTION

The step for forming borosilicate glass is typically carried out by reacting the reactants BBr₃ and O₂ and a surface of the silicon wafer in a tube furnace. In the reaction of BBr₃ and O₂, B₂O₃ is formed, which condenses on the surface of the silicon wafer and reacts with the surface to give boron-containing SiO₂, i.e., borosilicate glass. During the formation of borosilicate glass on the silicon wafer, the gaseous reactants typically flow into the tube furnace continually on one side of the tube furnace. On the other side of the tube furnace, gaseous reaction products or residues of the gaseous reactants are then removed from the tube furnace by means of a pump. As a result, the residence time of the reactants in the tube furnace is comparatively low and is typically below 60 sec, which poses no problem when using BBr₃ and O₂, as the reaction time of these reactants is only a few seconds. BBr₃, however, presents handling difficulties, being toxic and aggressive.

U.S. Pat. No. 8,691,677 B2 discloses a method in which BCl₃ and O₂ are used as reactants for forming borosilicate glass on silicon wafers. To carry out the method, the silicon wafers are provided in a tube furnace, which is shown in FIG. 1. The tube furnace 1 can be closed at one end by means of a door 5, and at an end 4 of the tube furnace 1 that lies opposite the door 5, there is a pump (not shown) arranged to allow the tube furnace 1 to be evacuated. Additionally arranged in the tube furnace 1 are feed tubes 2 for the separate feeding of BCl₃ and O₂. When the method is carried out, silicon wafers 3 are loaded through the door 5 into the tube furnace 1, producing a dead space 6 between the silicon wafers 3 and the door 5. The reactants in the form of BCl₃ and O₂, and N₂ as carrier gas, are flushed through the feed tube 2 into the tube furnace 1 in such a way that they are reacted in the dead space 6, which represents a separate reaction volume of the tube furnace 1, separate from the silicon wafers 3. The resultant products, including B₂O₃, are then passed in a continuous stream over the silicon wafers 3 and are used for forming the borosilicate glass on the silicon wafers. The direction of the fluids which flow during the procedure is indicated by the arrows. Relative to BBr₃ as a reactant, the use of BCl₃ as a reactant is accompanied by a variety of advantages, since it offers lower toxicity and aggressiveness and better handling. The reaction time of BCl₃ and O₂ to form B₂O₃, which is around 100 sec, is significantly longer by comparison with the reaction time of BBr₃ and O₂, however, which is around 6 sec. The typical residence time of the reactants in the tube furnace, however, is around 60 sec. BCl₃ and O₂ are therefore able only to react incompletely and very homogeneously over the length of the tube furnace 1. Because the reaction is carried out in the dead space 6 and the products resulting from the reaction of BCl₃ and O₂ are only subsequently passed over the silicon wafers 3, while the residence duration is relatively long, the deposition rate is nevertheless low and the resulting depositions are inhomogeneous.

### SUMMARY

It is an object of the invention to provide a method for producing a boron emitter on a silicon wafer that comprises a step for forming borosilicate glass, where homogeneous deposition and/or a sufficiently high deposition rate are achieved.

In accordance with the invention, the object is achieved by a method having the features of claim 1. Advantageous developments and modifications are specified in the dependent claims.

The invention relates to a method for producing a boron emitter on at least one silicon wafer which is arranged in a tube furnace, comprising a step for forming borosilicate glass on the silicon wafer, comprising in the sequence specified:
a) evacuating the tube furnace to a predetermined pressure,
b) flushing reactants, comprising BCl₃ and O₂, into the tube furnace and adjusting to a further predetermined pressure,
c) stopping the flushing after expiry of a predetermined time and allowing the reactants flushed in to react with each other and with a surface of the silicon wafer (3) over a predetermined duration, to form a layer with borosilicate glass on the surface of the silicon wafer (3), and
d) evacuating the tube furnace after expiry of the predetermined duration.

The invention is based on the fundamental concept of keeping the concentration of B₂O₃ in the tube furnace relatively constant and thereby achieving homogeneous deposition and also a more complete reaction. This is realized in that the step for forming borosilicate glass on the silicon wafer is performed in multiple stages. The method step of flushing in the reactants is substantially decoupled from the method step of reactant reaction. This is accomplished by first flushing the reactants into the tube furnace in defined quantities and with defined flow rates. The inflow of the reactants is then stopped, and the reactants react in the tube furnace as a closed system. It is possible as a result to allow the reactants to react in the environment of the silicon wafer, and so a more homogeneous deposition of borosilicate glass on the silicon wafers is achieved. Subsequently, reaction products formed in the reaction and any unreacted reactants are removed from the tube furnace. Through the substantial separation of the flushing in of the reactants from reaction of the reactants, it is possible to carry out the two steps individually with such optimization and control in terms of time that the deposition rate and quality of deposition are increased. The homogeneity of the deposition may be ascertained, for example, via measurement of an emitter sheet resistance.

The fluid stream cycles of the reactants and of the products are each controlled in individual steps separate from one another. First, in step b), the fluid inflow of the reactants is controlled, while in step c) the reaction of the reactants is controlled and in step d) the fluid outflow, comprising reaction products and any unreacted reactants, is controlled. Each step can be independently adjusted individually in its method parameters, and so the method overall runs in an optimized manner.

Step a) serves in particular to prepare step b) such that in step b) a defined amount of oxygen is flushed into the tube furnace. Step d) serves in particular to prevent degradation and/or exhaustion effects of the fluids present in the tube furnace.

In step b), BCl₃ and O₂ are flushed into the tube furnace. Additionally, a carrier gas, especially for BCl₃, may be flushed into the tube furnace in step b). The carrier gas used is preferably N₂. The phrase “stopping the flushing” means that no further reactants flow into the tube furnace anymore, the supply of the reactants instead being halted. In step b) the tube furnace is preferably also not evacuated. In other words, a pump provided for evacuating the tube furnace is deactivated or switched off in step b). The tube furnace in step b) forms a closed system. Fluids are neither actively supplied to nor actively removed from the closed system.

The B₂O₃ formed in the reaction of BCl₃ and O₂ is a liquid under the conditions prevailing in the tube furnace during this reaction, and in the tube furnace is present in the form of an aerosol.

The phrase “evacuating the tube furnace” in step d) means that the pressure in the tube furnace is brought to a level of 0 mbar, up to 1 mbar, preferably up to 10 mbar.

To perform steps a) to d), the tube furnace used for the method preferably comprises a door through which the at least one silicon wafer is loaded into the tube furnace. Additionally provided is a pump which is arranged at a side opposite the door and that is configured to evacuate the tube furnace, and feed tubes which are configured to supply the reactants individually and optionally by means of a carrier gas. Also provided is a heating facility configured to heat the tube furnace to the desired reaction temperature.

Steps b) to d) are preferably repeated cyclically. This allows a desired amount of borosilicate glass to be generated in a simple way. For example, steps b) to d) are repeated two to four times.

In one preferred embodiment, the predetermined pressure is up to 15 mbar, preferably 1 to 14 mbar, more preferably 7 to 12 mbar. This ensures that there is no oxygen or air or other unwanted fluids in the tube furnace. Before and/or during step a), the tube furnace may be flushed with an inert gas such as N₂. This additionally ensures that there is no O₂ in the tube furnace.

The further predetermined pressure is preferably higher than the predetermined pressure. The further predetermined pressure is preferably in the range from 20 to 200 mbar, preferably 20 to 170 mbar, more preferably 20 to 150 mbar.

In one preferred embodiment, step c) is carried out at a temperature in the range from 800 to 1000° C., preferably 820 to 950° C., more preferably 850 to 910° C.

With preference, the predetermined time is in the range from 10 to 120 sec, preferably in the range from 20 to 100 sec, more preferably in the range from 30 to 60 sec. The predetermined duration is preferably in the range from 2 min to 20 min, with particular preference in the range from 3 min to 15 min and more preferably still 5 min to 10 min. The reactants and, optionally, the carrier gas are flushed in relatively rapidly in step b), while the reactants in step b) are given a reaction time which is long by comparison therewith. The background to this is that the deposition taking place as a result of the reaction takes place as far as possible under constant and consistent conditions. As a result, sufficiently homogeneous deposition is achieved.

Step a) is preferably carried out in a further time in the range from 10 to 120 sec, with particular preference in the range from 20 to 100 sec and more preferably still in the range from 30 to 60 sec. The evacuation time is relatively short. This saves on time and costs.

Step d) is preferably carried out in yet a further time in the range from 10 to 120 sec, preferably in the range from 20 to 100 sec, more preferably still in the range from 30 to 60 sec. The relatively rapid evacuation of the tube furnace in step d) serves to prevent a depletion effect of the fluids present in the tube furnace. The fluids are then removed relatively rapidly from the tube furnace.

In one preferred embodiment, the reactants in step b) are flushed into the tube furnace in such a way that BCl₃ is flushed in through a feed tube having an outlet end into the tube furnace and O₂ is flushed in through a further feed tube having an outlet end into the tube furnace, so that BCl3 and O2 mix with each other in the tube furnace at the mutually adjacently arranged outlet ends of the feed tube and of the further feed tube in the tube furnace. The output ends are preferably mutually adjacently arranged, so that the reactants are able to react rapidly on entry into the tube furnace. In the sense of the invention, the expression “adjacently” denotes a distance of less than 1 cm between the center points of the outlet ends of the two feed tubes.

In one preferred embodiment, the reactants mix with each other in step b) in a region of the tube furnace in which the at least one silicon wafer is arranged. As a result, the reactants react in the immediate vicinity of the silicon wafer. This minimizes a path length which the B₂O₃ must travel in order to react with the surface of the silicon wafer. Additionally, a more homogeneous deposition is achieved by this means. In particular, there is no substantial dead space between a door of the tube furnace through which a wafer boat having a multiplicity of semiconductor wafers arranged thereon is loaded into the oven, and the wafer boat. In other words, the dead space between the wafer boat and the door is significantly shorter than 10% of the wafer boat.

Preferably, during the method, multiple silicon wafers are arranged in a wafer boat in the tube furnace, the distance of the silicon wafers from one another being less than 5 mm and preferably less than 3 mm. As a result, the method is additionally efficient and suitable for mass production. The tube furnace is a diffusion furnace.

In one preferred embodiment, between steps c) and d), a further step is carried out in which the tube furnace is flushed with an inert gas such as N₂. The inert gas flushing is carried out preferably in a period of 10 to 120 sec, with particular preference in the range from 20 to 100 sec and more preferably still in the range from 30 to 60 sec.

The borosilicate glass generated on a surface of the silicon wafer by means of steps a) to d) serves as a doping source for forming the boron emitter. Preferably, for producing the boron emitter on the silicon wafer, after step d) a step e) of injecting N₂ and after step e) a step f) of oxidizing with O₂ are carried out.

Step e) is carried out preferably in an atmosphere of pure N₂, with the expression “pure” meaning that the N₂ may comprise no more than technical impurities. Step e) is carried out preferably at a pressure in the range from 600 to 1000 mbar, with particular preference in the range from 700 to 900 mbar and more preferably still in the range from 750 to 850 mbar. Step e) is additionally carried out preferably at a temperature of 850 to 1150° C., with particular preference in the range from 900 to 1100° C. and more preferably still from 950 to 1050° C.

Step f) is carried out preferably using an N₂/O₂ mixture. An O₂ concentration in the N₂/O₂ mixture is preferably 40% to 100%, with particular preference 45% to 100% and more preferably still 50% to 100%. Step f) is carried out preferably at a temperature in the range from 850 to 1150° C., with particular preference in the range from 900 to 1100° C. and more preferably still in the range from 950 to 1050° C.

### BRIEF DESCRIPTION OF THE DRAWINGS

The invention is elucidated in more detail below with reference to figures. In the figures, schematically and not to scale:

FIG. 1 shows a cross-sectional view of a tube furnace used in the prior art in a method for producing a boron emitter on a silicon wafer;

FIG. 2 shows a cross-sectional view of a tube furnace used in a method according to the invention for producing a boron emitter on a silicon wafer; and

FIG. 3 shows a method flow diagram of the method according to the invention.

### DETAILED DESCRIPTION

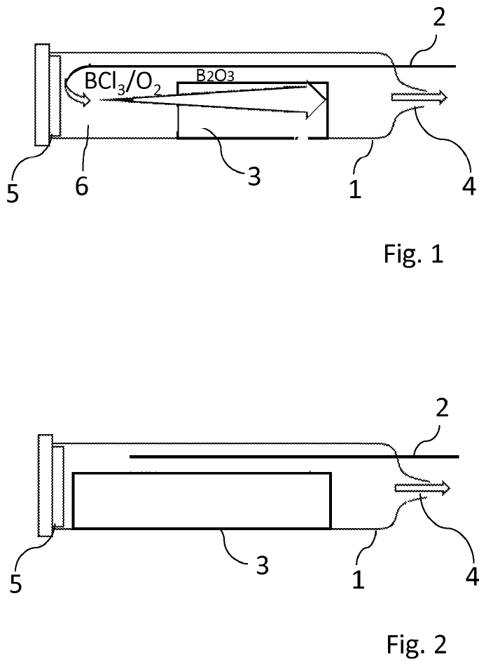

FIG. 1 shows a cross-sectional view of a tube furnace used in the prior art in a method for producing a boron emitter on a silicon wafer. To elucidate the tube furnace shown in FIG. 1, reference is made to the prior art set out in the introductory part of the description.

FIG. 2 shows a cross-sectional view of a tube furnace used in a method according to the invention for producing a boron emitter on a silicon wafer. The tube furnace 1 shown in FIG. 2 corresponds to the tube furnace shown in FIG. 1, with the difference that it has no dead space. Instead, in the step for forming borosilicate glass on the silicon wafer, the reactants BCl₃ and O₂ and optionally N₂ as carrier gas are flushed into the tube furnace 1 in such a way that BCl₃ is flushed through a feed tube 2 into the tube furnace 1 and O₂ is flushed through a further feed tube (not shown) into the tube furnace 1, so that they mix with each other in the tube furnace 1 at the outlet ends (not shown) of the feed tube 2 and of the further feed tube in the tube furnace 1, the reactants being flushed into the tube furnace 1 in such a way that they mix with each other in a region of the tube furnace 1 in which the silicon wafers 3 are arranged, to react with one another there. The outlet ends are mutually adjacently arranged. After the flushing has been stopped, after expiry of a predetermined time, and after the reactants flushed in have been allowed to react with each other and with a surface of the silicon wafer over a predetermined duration, to deposit borosilicate glass on the surface of the silicon wafer, the tube furnace 1 is evacuated via activation of the pump (not shown) arranged at the end 4 of the tube furnace 1, with products and any unreacted reactants being removed in arrow direction from the tube furnace 1.

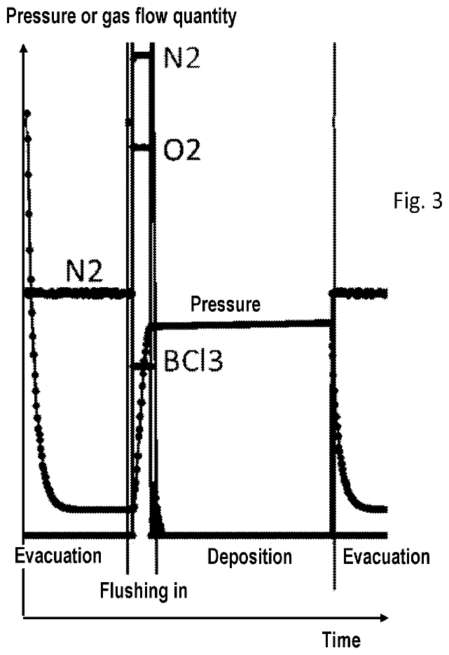

FIG. 3 shows a method flow diagram of the method according to the invention. A temporal sequence of the method is shown, in terms of pressure conditions and fluid and gas feed conditions in the tube furnace shown in FIG. 2. The method flow is shown purely schematically, and there are therefore no units given on the axes. The method according to the invention for producing a boron emitter on a silicon wafer arranged in the tube furnace shown in FIG. 2 comprises a step for forming borosilicate glass on the silicon wafer that is configured in multiple stages. In the temporal sequence indicated, this step comprises:
a) evacuating the tube furnace to a predetermined pressure, where optionally nitrogen can be flushed into the tube furnace at the same time,
b) flushing reactants, comprising BCl₃ and O₂, and N₂ as carrier gas into the tube furnace and adjusting to a further predetermined pressure, which is greater than the predetermined pressure in step a), the gas flow quantity of O₂ being greater than the gas flow quantity of BCl₃,
c) forming the borosilicate glass via stopping the flushing after expiry of a predetermined time and allowing the reactants flushed in to react with each other and with a surface of the silicon wafer over a predetermined duration, to deposit borosilicate glass on the surface of the silicon wafer, and
d) evacuating the tube furnace after expiry of the predetermined duration.

The predetermined duration here is substantially greater than the predetermined time. Steps a) and d) as well are carried out in a shorter time than step c).

The method according to the invention is additionally elucidated in more detail with reference to an example.

### Example

The method for producing a boron emitter on a silicon wafer arranged in a tube furnace comprises a step for forming borosilicate glass on the silicon wafer. The step for forming borosilicate glass on the silicon wafer is a multistage step and is carried out as follows: A wafer boat charged with multiple silicon wafers is provided in the tube furnace. The tube furnace is heated to a temperature of 870° C. In a step a), the tube furnace is evacuated to a predetermined pressure of 0 mbar during a time of 5 min. The tube furnace is held at the temperature of 870° C. in step a). Step a) is followed by a step b), in which reactants, comprising BCl₃ and O₂, are flushed into the tube furnace at a further predetermined pressure of 50 mbar in a predetermined time of 30 sec, while the tube furnace is held at a temperature of 870° C. The gas volume flow of O₂ in step b) is 1000 sccm, while the gas volume flow of BCl₃ is 100 sccm; N₂ may be used as carrier gas. After the expiry of the predetermined time, a step c) is carried out in which the gas feed is stopped and the reactants flushed in are allowed to react with each other and with a surface of the silicon wafer over a predetermined duration of 30 min, to deposit borosilicate glass on the surface of the silicon wafer. In step c), the tube furnace is additionally held at a temperature of 870° C. After the 30 min have elapsed, the tube furnace is flushed at a temperature of 870° C. for 30 sec with N₂ with a gas volume flow of 5000 sccm. The tube furnace is subsequently evacuated at a temperature of 870° C. for 1 min to a pressure of 0 mbar.

From step b) onward, the method is repeated three times, to generate a desired borosilicate layer thickness on the silicon wafer. The step for forming borosilicate glass on the silicon wafer is then carried out.

To produce the boron emitter on the silicon wafer, the following steps are additionally performed: After step d), a step e) is carried out in which N₂ is injected with a gas volume flow of 5000 sccm at a temperature of 980° C. and a pressure of 900 mbar over 15 min. Step e) is followed by a step f), in which an oxidation is carried out in a mixture of N₂ and O₂. Step f) is carried out at a pressure of 900 mbar, with the gas volume flow of O₂ in step f) being 10000 sccm. Step f) is carried out a temperature of 980° C. over 10 min, after which the temperature is raised to 990° C. and maintained over 120 min.

### LIST OF REFERENCE SIGNS

1 Tube furnace
2 Feed tube
3 Silicon wafer
4 End
5 Door
6 Dead space

1. A method for producing a boron emitter on at least one silicon wafer which is arranged in a tube furnace, comprising a step for forming borosilicate glass on the silicon wafer, comprising in the sequence specified:
a) evacuating the tube furnace to a predetermined pressure,
b) flushing reactants, comprising BCl₃ and O₂, into the tube furnace and adjusting to a further predetermined pressure,
c) stopping the flushing after expiry of a predetermined time and allowing the reactants flushed in to react with each other and with a surface of the silicon wafer over a predetermined duration, to form a layer with borosilicate glass on the surface of the silicon wafer, and
d) evacuating the tube furnace after expiry of the predetermined duration.

2. The method as claimed in claim 1, wherein steps b) to d) are repeated cyclically.

3. The method as claimed in claim 1, wherein the predetermined pressure is up to 15 mbar and/or the further predetermined pressure is in the range from 20 to 200 mbar.

4. The method as claimed in claim 1, wherein step c) is carried out at a temperature in the range from 800 to 1.000° C.

5. The method as claimed in claim 1, wherein the predetermined time is in the range from 10 to 120 sec, and/or the predetermined duration is in the range from 2 min to 20 min, and/or step a) and/or d) are carried out in a further time in the range from 10 to 120 sec.

6. The method as claimed in in claim 1, wherein the reactants in step b) are flushed into the tube furnace in such a way that BCl₃ is flushed through a supply tube having an outlet end into the tube furnace and O₂ is flushed through a further supply tube having an outlet end into the tube furnace, so that BCl₃ and O2 mix with each other in the tube furnace at the mutually adjacently arranged outlet ends of the supply tube and of the further supply tube in the tube furnace.

7. The method as claimed in in claim 1, wherein the reactants in step b) are flushed into the tube furnace in such a way that they mix with each other in a region of the tube furnace in which the silicon wafer is arranged.

8. The method as claimed in claim 1, wherein during the method, multiple silicon wafers are arranged in a wafer boat in the tube furnace and are subjected to the method simultaneously, the distance of the silicon wafers from one another being less than 5 mm.

9. The method as claimed in claim 1, wherein between steps c) and d), a further step is carried out in which the tube furnace is flushed with an inert gas.

10. The method as claimed claim 1, wherein for producing the boron emitter on the silicon wafer, after step d) a step e) of injecting N₂ and after step e) a step f) of oxidizing with O₂ are carried out.

11. The method as claimed in claim 1, wherein the predetermined pressure is in a range from 1 to 14 mbar and/or the further predetermined pressure is in a range from 20 to 170 mbar.

12. The method as claimed in claim 1, wherein the predetermined pressure is in a range from 7 to 12 mbar and/or the further predetermined pressure is in a range from 20 to 150 mbar.

13. The method as claimed in claim 1, wherein step c) is carried out at a temperature in a range from 820 to 950° C.

14. The method as claimed in claim 1, wherein step c) is carried out at a temperature in a range from 850 to 910° C.

15. The method as claimed in claim 1, wherein the predetermined time is in a range from 20 to 100 sec, and/or the predetermined duration is in a range from 3 min to 15 min, and/or step a) and/or d) are carried out in a further time in a range from 20 to 100 sec.

16. The method as claimed in claim 1, wherein the predetermined time is in a range from 30 to 60 sec, and/or the predetermined duration is in a range from 5 min to 10 min, and/or step a) and/or d) are carried out in a further time in a range from 30 to 60 sec.

17. The method as claimed in in claim 1, wherein during the method, multiple silicon wafers are arranged in a wafer boat in the tube furnace and are subjected to the method simultaneously, the distance of the silicon wafers from one another being less than 3 mm.
